(19) United States
(12) Patent Application Publication
(10) Pub. No.: US 2025/0062591 A1
(43) Pub. Date: Feb. 20, 2025

(54) ENCAPSULATION OF SIDE-EMITTING LASER PACKAGES BY MEANS OF VACUUM INJECTION MOLDING

(71) Applicant: ams-OSRAM International GmbH, Regensburg (DE)

(72) Inventors: Tobias Gebuhr, Bad Abbach (DE); Thomas Schwarz, Regensburg (DE); Michael Zitzlsperger, Regensburg (DE)

(21) Appl. No.: 18/577,562

(22) PCT Filed: Jul. 15, 2022
(86) PCT No.: PCT/EP2022/069907

§ 371 Date: Jan. 8, 2024

(30) Foreign Application Priority Data
Jul. 15, 2021 (DE) 10 2021 118 354.5

(51) Int. Cl. H01S 5/02234; H01S 5/02253; H01S 5/40

(52) U.S. Cl. CPC H01S 5/02234; H01S 5/02253; H01S 5/4031; H01S 5/4087

(57) ABSTRACT

In an embodiment a light emitting component includes at least one edge-emitting semiconductor element having a laser facet, wherein the edge-emitting semiconductor element is arranged on a carrier and is at least partially surrounded by a cap, which comprises a light emitting surface in a beam direction, wherein the cap is made by a vacuum injection molding process, and wherein the light emitting surface directly adjoins the laser facet of the edge-emitting semiconductor element.

### CROSS-REFERENCE TO RELATED APPLICATIONS

This patent application is a national phase filing under section 371 of PCT/EP2022/069907, filed Jul. 15, 2022, which claims the priority of German patent application 10 2021 118 354.5, filed Jul. 15, 2021, each of which is incorporated herein by reference in its entirety.

### TECHNICAL FIELD

The present invention relates to a light emitting component and a method for manufacturing a light emitting component.

### BACKGROUND

In the manufacture of QFN-based side-emitting laser diodes or laser diode arrays for use in LIDAR systems (light detection and ranging), for example, the bonded and contacted diodes are currently encapsulated with a clear silicone shell using a compression molding process.

One problem here is the high requirement for the optical exit surface in order to achieve both high light output and, above all, good beam quality. This exit window is created by molding in the molding tool. As a so-called release film (mold release film) is used in compression molding, the surface quality and shape accuracy of the exit window is restricted by the limited deformation of the release film. In addition, compromises in package design and production yield must be accepted. The main problems are
Negative influence on the beam quality of the laser beam (power loss, scattered light, restrictions in beam shaping due to the required minimum distance between the housing wall and laser facet. Mold tolerances (tolerances during injection molding) result in fluctuating material thickness in front of the laser facet and must therefore be maintained.
Yield loss in production due to film imprints, film folds during thermoforming of the release film onto the tool surface.
No precise contours of the decoupling window possible due to the minimum film thickness of 50 μm, resulting in a smallest radius when bending the release film at 50-100 μm.
Until now, the component has been encapsulated with clear silicone using a compression molding process, for example.
The problem of undesired deformation of the release film has not yet been solved. Higher yield losses and limited component performance must therefore be accepted.
When assembling the packages, there is a risk of solder or flux creeping between the silicone encapsulation and a carrier/lead frame on which the encapsulated diodes are bonded. This can lead to the encapsulation or the diodes becoming detached.

### SUMMARY

Embodiments provide a light emitting component with at least one light emitting semiconductor element which is arranged on a carrier and is at least partially surrounded by a cap with a light emitting surface, the cap being made by a vacuum injection molding process and a distance of less than 200 μm, in particular less than 100 μm, being provided between the light emitting surface (10) and an emitting surface of the light emitting semiconductor element.

As a result, a significantly better surface quality of the emission window or emission surface can be achieved. In addition, very small radii can be achieved at surface transitions on the emission surface, so that the geometry of the component can be designed more freely compared to the state of the art. A further advantage is the improved beam quality of the laser beam due to better surface quality of the emission window, as no film deformation is possible, as well as improved parallelism of the window, as there is no mapping of the film roughness on the surface. There is no risk of silicone flash on the back of the component due to the now pressureless encapsulation process. In addition, a more precise positioning of the lead frames in the tool is possible and thus an optimized positioning of the exit window in front of the laser facet. The improved positioning of the window means that the distance between the window and the laser facet can be reduced. This allows downstream optics to be moved even closer to the emitter, resulting in a higher power density and improved resolution of the LIDAR system.

In one embodiment of the invention, the cap is at least partially made of silicone, the silicone preferably being transparent. Additives which effect a wavelength conversion of the light emitted by the semiconductor element(s) may also be incorporated.

In one embodiment of the invention, the semiconductor element comprises a laser facet, whereby the front side of the laser facet is directly adjacent to the light emitting surface. As a result, the size of the component can be reduced, beam losses are reduced and the light quality is improved.

In one embodiment of the invention, the light emitting surface is arranged substantially perpendicular to a base surface of the carrier. Due to the fact that surfaces which are essentially parallel to the molding direction during demolding are to be produced during the casting of the cap, the problem arises, as with all casting processes, that surfaces of the molding tool and molded surfaces would have to be guided past each other in parallel. As a rule, therefore, slightly inclined surfaces must be provided in order to avoid damaging or at least roughening the molded surfaces. However, by dispensing with a release film and a compression molding process according to the invention, this angle can be made almost right-angled.

In one embodiment of the invention, one upper side of the carrier is flat. This dispenses with an etched trench arranged on the light extraction surface to create an L-shaped end profile.

In one embodiment of the invention, the light emitting surface adjoins the support at a right angle. The transition between the two is realized with a very small radius.

In one embodiment of the invention, several light emitting semiconductor elements are arranged on a common submount or substrate on the carrier; alternatively, several light emitting semiconductor elements are each arranged on individual submounts or substrates on the carrier.

In one embodiment of the invention, the plurality of light emitting semiconductor elements have different colors and may be so-called “multi-channel” semiconductor elements in one embodiment of the invention.

In one embodiment of the invention, the component comprises integrated driver electronics. This enables further miniaturization and easier connectivity of the components.

In one embodiment of the invention, the light emitting surface of the cap is convex or concave in shape, at least in certain areas. In this way, a beam shaping that is easy to realize can be achieved. In one embodiment of the invention, the light emitting surface of the cap has a molded lens for this purpose.

In one embodiment of the invention, a lens insert is arranged on the cap, the lens insert being at least a part of the light emitting surface. In one embodiment of the invention, the lens insert is made of a material different from the material of the cap, preferably glass.

In a further embodiment of the invention, a beam combiner is arranged in the cap, which in one embodiment is made of glass.

Further embodiments provide a method of manufacturing a plurality of emitting components each having at least one light emitting semiconductor element, comprising the steps of
a) Providing a printed circuit board substrate;
b) Encapsulating a part of the PCB substrate with a curable plastic to produce an encapsulation;
c) Arranging, fixing and wiring several semiconductor elements on the printed circuit board substrate;
d) Inserting the printed circuit board substrate with the semiconductor elements into a lower mold tool;
e) Placing an upper mold tool on the lower mold tool so that the circuit board substrate is accommodated in a closed cavity;
f) Creating a vacuum in the cavity of the mold tool;
g) Encapsulating the semiconductor elements with a curable plastic;
h) Demolding the substrate with the light emitting elements embedded in plastic;
i) Separating of components.

In one embodiment of the invention, it is provided that the mold tool comprises at least one slider which is brought into a first position in process step g) and is brought into a second position in a process step g-1) which takes place between process steps g) and h).

In one embodiment of the invention, it is provided that the slider has a concave recess for producing a convex lens, or the slider has a convex recess for producing a concave lens.

In one embodiment of the invention, it is provided that an insert is introduced into the mold before or after process step d).

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a first embodiment of an arrangement of a plurality of light emitting components according to the invention on a lead frame in a spatial view according to some aspects of the proposed principle;

FIG. 2 shows an enlarged section of FIG. 1 to illustrate further aspects;

FIG. 3 shows a further embodiment of a light emitting component in a spatial view according to some aspects of the proposed principle;

FIG. 4 shows a section through the component of FIG. 3 in a spatial illustration;

FIG. 5 shows a schematic section through two components arranged on either side of one of the parting lines;

FIGS. 6 and 7 show schematic illustrations of the component as shown in FIGS. 3 and 4;

FIGS. 8 and 9 show schematic illustrations of a further embodiment of a component in section and plan view, respectively, according to some aspects of the proposed principle;

FIGS. 10 to 13 show further embodiments of components, each in a plan view according to some aspects of the proposed principle;

FIG. 14 shows a further embodiment of a component in a sectional view according to some aspects of the proposed principle;

FIG. 15 shows a sketch of the manufacturing process for the embodiment of FIG. 14;

FIG. 16 shows a sectional view of a further embodiment of a component according to some aspects of the proposed principle; and

FIGS. 17 and 18 show schematic illustrations of a further embodiment of a component in sectional view and according to the proposed principle in plan view.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

The present invention relates primarily to the manufacture of components using vacuum injection molding, VIM. This uses a vacuum in the mold tool to suck the liquefied molding compound into the cavity. The design of the mold tool is chosen in such a way that possible air pockets are avoided when filling in the liquid mass, so that the mass completely fills the available space. There is no need for additional release foils between the compound and the mold tool, so that sharp edges with a very small radius can be reached. Due to the negative pressure, the compound is also drawn into small gaps. In some cases, VIM is a special form of the injection molding process, as the molding compound is usually liquid and has a lower viscosity than other processes.

In compression molding, on the other hand, the liquid molding compound is supplied via an external pressure which, depending on the application, is also maintained during the cooling process. However, one possible disadvantage of this type of process is so-called flashing, in which the mold compound penetrates into edge areas between parts of the mold tool. Sharp edges or very small radii are therefore only possible to a limited extent with this process. To improve this somewhat, a compressible film can also be placed on the mold tool. This can be removed after the process. However, the film itself has a certain thickness, which limits the radius of the edges. In addition, the film must fit snugly, i.e. it must not curl or otherwise deform during the process.

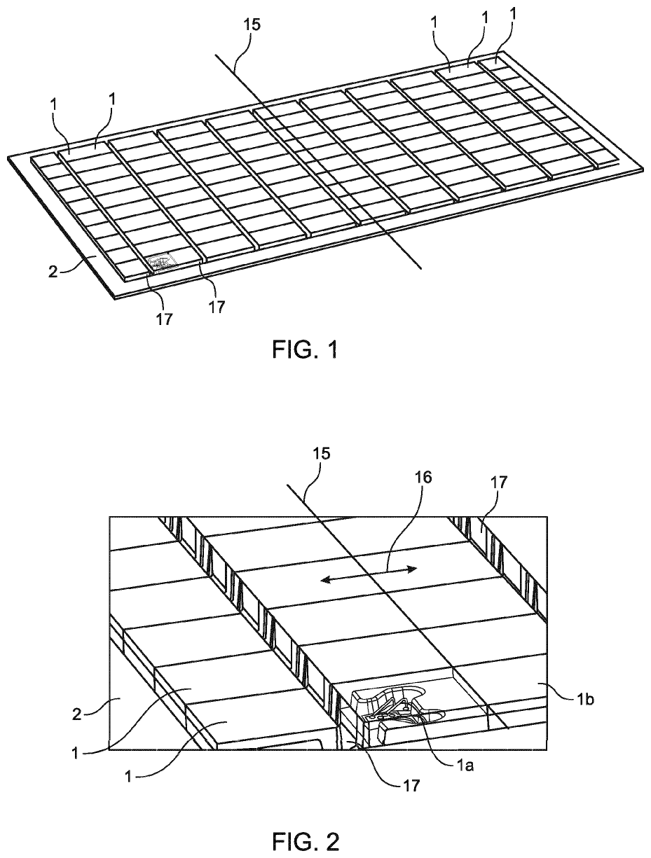

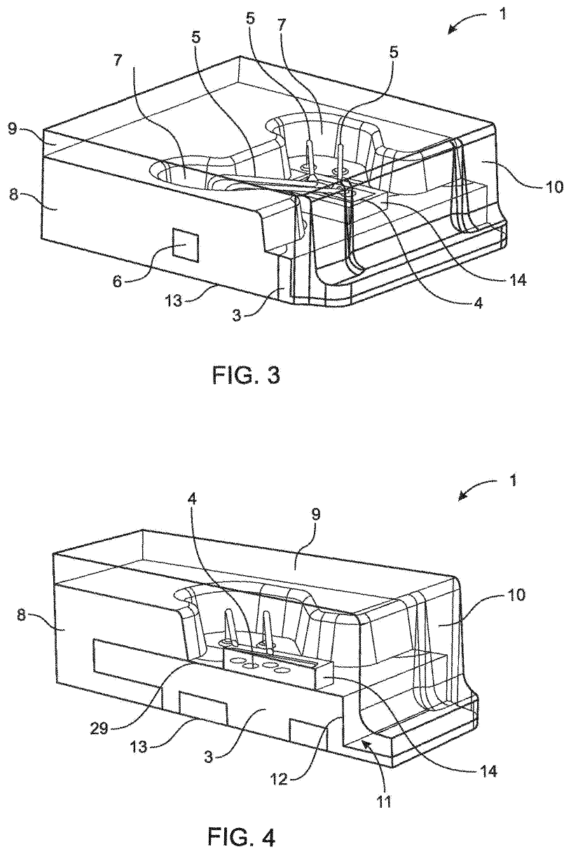

FIG. 1 shows the arrangement of a plurality of side-emitting lasers as light emitting components 1 on a lead frame 2 before the components 1 are separated. A single component 1 is shown in spatial representation in FIG. 3 and in a spatial section in FIG. 4. Each component 1 comprises a carrier 3, which is part of the lead frame 2 before the components 1 are separated and is made of metal such as copper, for example, on which a laser diode 4 is arranged and electrically connected by wires 5 to contacts, of which only one contact 6 can be seen in FIG. 3. The laser diode 4 is surrounded in a cavity 7 in an encapsulation 8, for example made of a thermosetting material mixed with a reflective agent, such as epoxy, or a white-colored silicone. A cap 9 made of transparent silicone is arranged over the encapsulation and in the cavity 7. The cavity 7 is open towards a light emitting surface 10, so that the light emitting surface 10 is formed by the cap 9. The carrier 3 has a step 11 on the side of the light emitting surface 10, so that the carrier 3 has an L-shaped contour on the side of the light emitting surface 10 in the side view. The material of the cap 9 covers both an upper side 29 of the encapsulation 8 and a front side 12 of the step 11. The light exit surface 10 is practically perpendicular to a base surface 13 of the component 1. The laser diode 4 is essentially cuboidal, so that its front laser facet, hereinafter more generally referred to as exit surface 14, is also perpendicular to the base surface 13 of the component 1 and the exit surface 14 and light exit surface 10 are thus practically parallel, insofar as this is permitted by the method for casting the cap 9 described below.

The components 1 are arranged next to each other in rows 15 for production. In a row 15, as can be seen in particular in FIG. 2, apart from the rows 15 arranged at the edge, two components 1a and 1b are arranged next to each other in the longitudinal direction, which is indicated by a double arrow 16, in such a way that the respective light emitting surfaces 10 face a parting line 17.

To manufacture individual components 1, a printed circuit board substrate 2 is provided in a manufacturing step a) and the encapsulation 8 is molded in a manufacturing step b).

In production step c), the laser diodes 4 are arranged, fixed and wired on the PCB substrate 2. This step can also take place before the encapsulations 8 are cast. The printed circuit board substrate 2 with the semiconductor elements is then placed in a lower mold in production step d) and an upper mold 18 is placed on the lower mold in production step e) in such a way that the printed circuit board substrate 2 is accommodated in a closed cavity in which there are cavities for the caps to be cast.

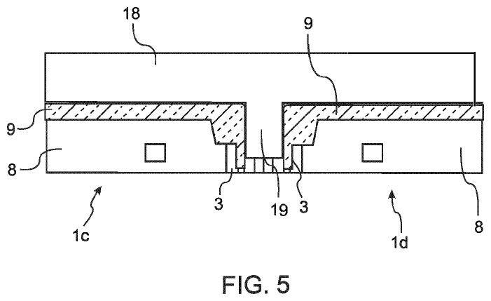

FIG. 5 shows a schematic section through two components 1c and 1d arranged on either side of one of the parting lines 17. The parting line 17 is created by a bar 19 of the upper mold 18. In the next production step f), a vacuum is generated in the cavities of the mold tool for the caps 9 shown hatched in FIG. 5. In a production step g), plastic is injected into the cavities (so-called vacuum injection molding), so that the semiconductor elements are encapsulated with a curable plastic. The substrate with the semiconductor elements embedded in plastic is then formed in production step h) and the semiconductor elements are separated in production step i). In this way, the individual edges are significantly narrower and the curve radius around the edge is reduced compared to production with film.

The light emitting surface 10, see FIG. 4, merges with a radius R1 into an edge 20 running essentially parallel to the base surface 13. The radius R1 can be made significantly smaller than in the prior art by the vacuum injection molding described above and has radii smaller than 100 μm.

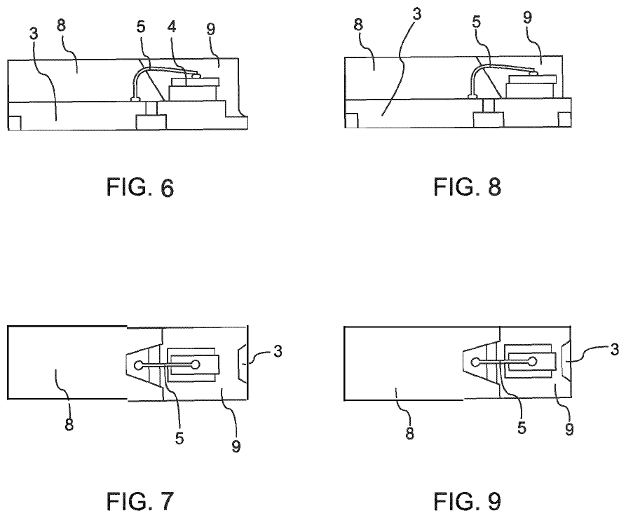

FIGS. 6 and 7 show schematic representations of the component according to the invention as shown in FIGS. 3 and 4. FIG. 6 is a longitudinal section, FIG. 7 is a plan view. FIGS. 8 and 9 show schematic representations of a further embodiment example of a component 1 according to the invention in section and plan view, respectively. In the embodiment example of FIGS. 8 and 9, step 11 is omitted. This is made possible by the vacuum injection molding described above for molding the cap 9, since the elimination of a separating film means that the bar 19 of the upper molding tool 18 can be fed practically up to the surface of the printed circuit board substrate 2 and a radius R1, as described with reference to FIG. 4, can therefore be dispensed with.

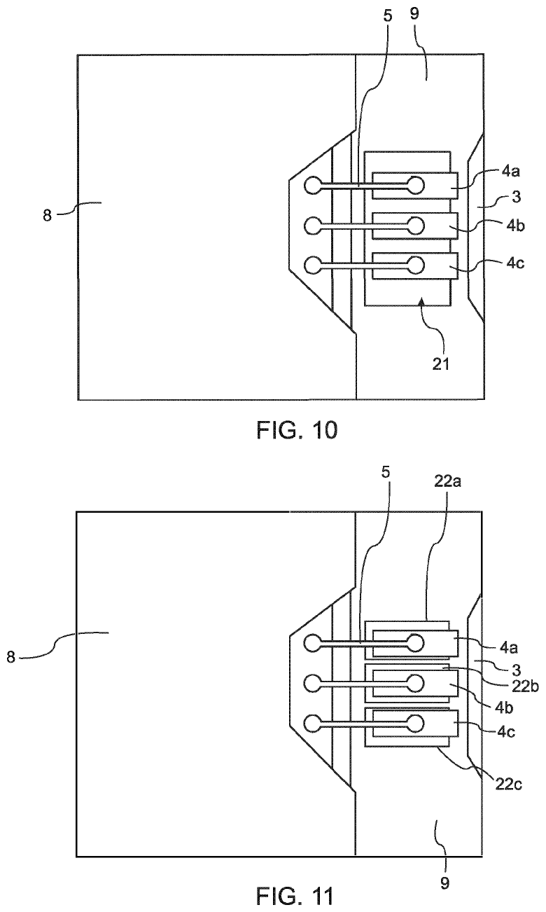

The proposed method also allows the lead frame 3 to be designed differently and, in particular, with a reduction as shown in the side view of FIG. 8. The reduction is located at the bottom right edge and is filled with material from the encapsulation 8. The respective top views also show the slight retraction of the transparent material of the cap 9, which can be seen even more clearly in the top views of FIGS. 10 and 11. These bulges, in which the material of the printed circuit board 3 is exposed, comprise a longitudinal side—corresponding to the exit surface of the cap, which runs essentially parallel to the laser facets—and two side surfaces connected to it, which open at a flat angle, for example in the range of 45° to 75°. This reduces possible tension during production and creates a smooth surface.

FIGS. 10 and 11 show two further embodiments of components 1 according to the invention in a top view. In the embodiment example of FIG. 10, laser diodes 4a, 4b, 4c of different colors are arranged on a common substrate 21, while in the embodiment example of FIG. 11, laser diodes of different colors are arranged on separate substrates 22a, 22b, 22c. In this case, the exit surface of the cap 9 is arranged parallel to all three laser facets. Injection molding allows the surface to be brought quite close to the laser facets, so that the distance between the surface of the cap and the laser facets is in the range of less than 100 μm, possibly up to a few 10 μm. One of the reasons for this is that injection molding eliminates the large radii of curvature that previously occurred in the area of the exit surface of the cap.

A further advantage can result from the fact that the elimination of the previously occurring large radii of curvature in the area of the exit surface of the cap also enables a greater distance between the light exit surface and the laser facet. In previous components, curvatures of the light emitting surface can protrude into the light cone of the laser diodes and have a negative effect on it. One advantage of a larger distance can be that the light cone from the laser is already larger. On the one hand, this can reduce the beam intensity of the laser, and on the other hand, dust particles or similar impurities on the light emitting surface heat up less. The service life of the optical surface or light emitting surface can thus be increased.

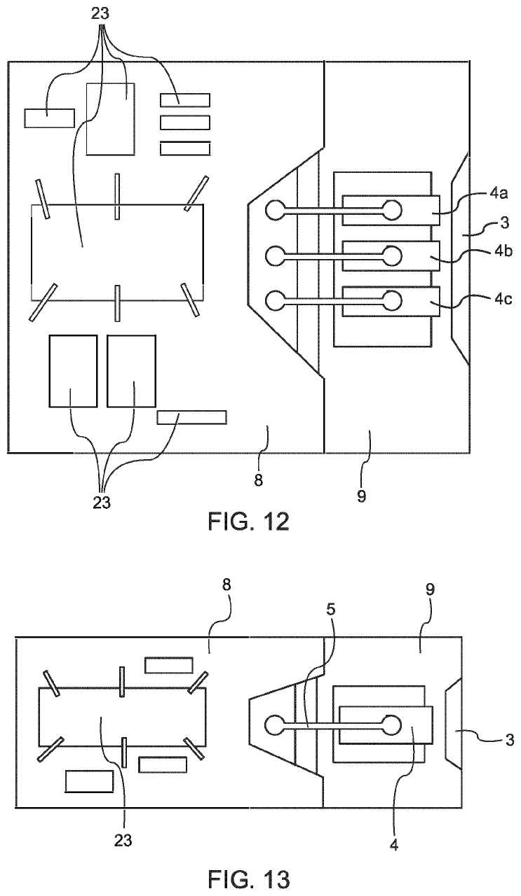

FIGS. 12 and 13 show two further embodiments of components 1 according to the invention in a top view. In these, driver electronics 23 are arranged in the encapsulation 8.

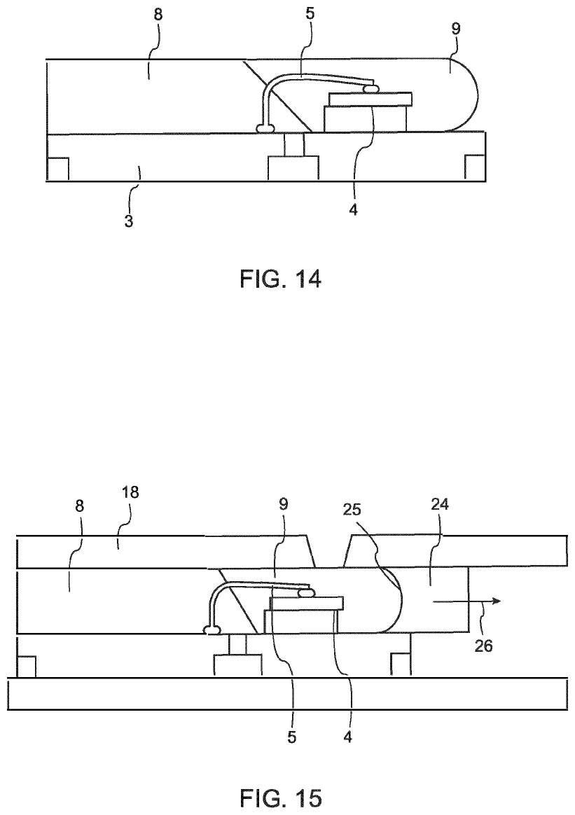

FIG. 14 shows a sectional view of a further embodiment of a component 1 according to the invention. The light outlet opening 10 is convex here in the form of a lens, although this does not protrude beyond the material of the carrier or lead frame 3. This allows the lens to be protected from damage, for example. The mold material, which is located on the rear wall of the carrier 3 in the area of the edges, can also be seen in this sectional view. This is where the separation takes place during production, so it is advisable to use easily separable mold material at these positions.

FIG. 15 illustrates their production. When casting the cap 9, a slider 24 of the lower or upper mold is first brought into a first, front position as shown in FIG. 15. The slider 24 comprises a concave recess 25 for producing the convex lens of the light outlet opening 10 For demolding, the slider 24 is moved in the direction of the arrow 26 to a second, rear position so that it releases the lens and can be molded.

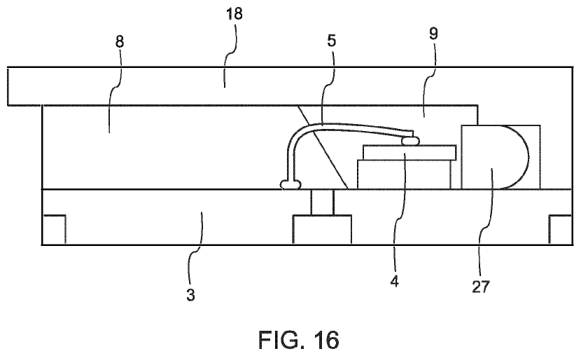

FIG. 16 shows a sectional view of a further embodiment of a component 1 according to the invention. The light exit opening 10 here comprises a glass insert 27 designed as a lens, for example a “fast axis collimator” lens (FAC). The insert 27 is placed in a production step d-2) arranged after production step d), the insertion of the printed circuit board substrate 2 into the lower mold tool, at the corresponding position of the lower mold tool or the upper mold tool 18 and is also cast in. In this embodiment, the mold should be elastically shaped in the area of the lens in order to prevent damage or destruction. For example, the molding tool can comprise or be formed from polydimethylsiloxane (PDMS) in order not to damage the insert 27. Furthermore, as shown in the figure, it may be provided that the insert 27 does not touch the molding tool on its light exit side in order to prevent damage to the light exit side. The molding tool can also be designed in such a way that it seals the area to be cast around the lens so that the cap 9 can be formed at the desired position and in the desired shape and size.

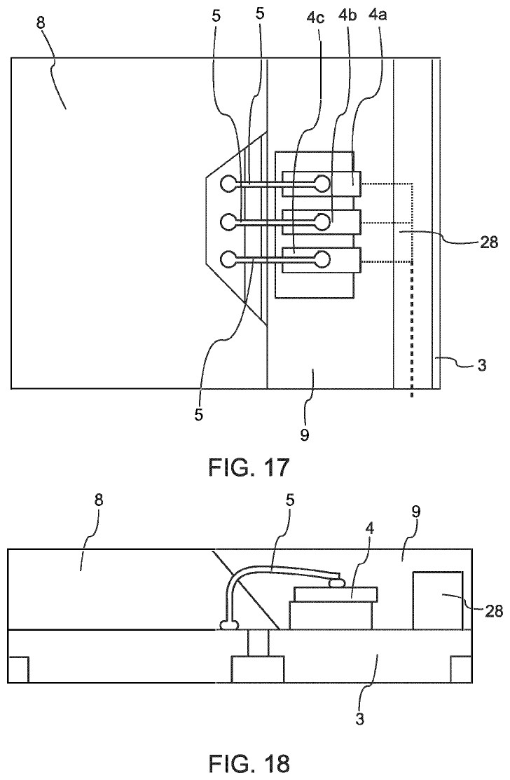

FIGS. 17 and 18 show schematic representations of a further embodiment example of a component 1 according to the invention in section or in plan view. In the embodiment example of FIGS. 17 and 18, laser diodes 4a, 4b, 4c of different colors are provided with a beam combiner 28, which is arranged between the laser diodes 4a, 4b, 4c and the light exit opening 10. This can be applied to the lead frame in a first manufacturing step. It is then completely surrounded by the transparent cap 9. The beam combiner 28 can be designed in particular to combine the light emitted by the laser diodes 4a, 4b, 4c and deflect it by approximately 90°, as in the case shown. For this purpose, the beam combiner 28 can, for example, comprise mirrors or reflective elements that deflect the individual light beams.

Accordingly, the combined light beam cannot, for example, emerge from the component along the main emission direction of the laser diodes 4a, 4b, 4c or from the light exit opening mentioned at the beginning, but can, for example, emerge from the component along the dashed line, as in the case shown.

However, it is also conceivable that the combined light is deflected in a direction not shown and/or the beam combiner 28 can, for example, also comprise several mirrors or reflective elements that deflect the combined light several times.

A combination of a lens as shown in FIGS. 14, 15 and 16, for example a “fast axis collimator” lens, and a beam combiner as shown in FIGS. 17 and 18 would also be possible. This has the advantage that different divergences of the individual emitters can be adapted to each other by means of the lens before their beams are combined by means of the beam combiner. In particular, this can result in improved convergence of the individual colors of the individual emitters.

1-23. (canceled)

24. A light emitting component comprising:
at least one edge-emitting semiconductor element comprising a laser facet,
wherein the edge-emitting semiconductor element is arranged on a carrier and is at least partially surrounded by a cap, which comprises a light emitting surface in a beam direction,
wherein the cap is made by a vacuum injection molding process, and
wherein the light emitting surface directly adjoins the laser facet of the edge-emitting semiconductor element.

25. The light emitting component according to claim 24, wherein the cap is at least partially made of silicone.

26. The light emitting component according to claim 24, wherein the light emitting surface is arranged substantially perpendicular to a base surface of the carrier.

27. The light emitting component according to claim 24, wherein an upper side of the carrier is flat.

28. The light emitting component according to claim 24, wherein the light emitting surface adjoins the carrier at a right angle.

29. The light emitting component according to claim 24, wherein the light emitting surface is at least partially set back with respect to a carrier edge.

30. The light emitting component according to claim 24, wherein a plurality of light emitting semiconductor elements are arranged on a common submount substrate on the carrier.

31. The light emitting component according to claim 30, wherein the plurality of light emitting semiconductor elements have different colors.

32. The light emitting component according to claim 30, wherein the plurality of light emitting semiconductor elements are multi-channel semiconductor elements.

33. The light emitting component according to claim 24, wherein a plurality of light emitting semiconductor elements are each arranged on individual submount substrates on the carrier.

34. The light emitting component according to claim 24, wherein the light emitting component comprises integrated driver electronics.

35. The light emitting component according to claim 24, the light emitting surface of the cap is at least partially convex in shape.

36. The light emitting component according to claim 24, wherein the light emitting surface of the cap is at least partially concave in shape.

37. The light emitting component according to claim 24, wherein the light emitting surface of the cap has an integrally formed lens.

38. The light emitting component according to claim 24, further comprising a lens insert arranged on the cap, wherein the lens insert forms at least a portion of the light emitting surface.

39. The light emitting component according to claim 38, wherein the lens insert comprises a material different from the material of the cap.

40. The light emitting component according to claim 39, wherein the lens insert is made of glass.

41. The light emitting component according to claim 39, further comprising a beam combiner arranged in the cap.

42. The light emitting component according to claim 41, wherein the beam combiner is made of glass.

43. A method for manufacturing a plurality of light emitting components each comprising at least one light emitting semiconductor element, the method comprising:
providing a printed circuit board substrate;
encapsulating a portion of the printed circuit board substrate with a curable plastic to produce an encapsulation;
arranging, fixing and wiring a plurality of semiconductor elements on the printed circuit board substrate, the plurality of semiconductor elements forming edge-emitting semiconductor lasers having a laser facet;
inserting the printed circuit board substrate with the semiconductor elements into a lower mold tool;
placing an upper mold tool on the lower mold tool so that the printed circuit board substrate is accommodated in a closed cavity;
creating a vacuum in the cavity of the mold tool;
encapsulating the semiconductor elements with a curable plastic in such a way that the curable plastic is directly adjacent to the laser facet;
demolding the substrate with the light emitting elements embedded in plastic; and
separating the components.

44. The method according to claim 43, wherein the mold tool comprises at least one slider which is brought into a first position while the semiconductor elements are encapsulated and is brought into a second position between encapsulating the semiconductor elements with the curable plastics and demolding the substrate.

45. The method according to claim 44, wherein the slider has a concave recess for producing a convex lens, or the slider has a convex recess for producing a concave lens.

46. The method according to claim 43, further comprising introducing an insert into the mold tool directly before or after inserting the printed circuit board substrate into the lower mold too.
